(19) United States
(12) Patent Application Publication
(10) Pub. No.: US 2025/0267969 A1
(43) Pub. Date: Aug. 21, 2025

(54) IMAGE SENSOR

(71) Applicant: SK hynix Inc., Icheon-si (KR)

(72) Inventor: Min Su CHO, Icheon-si (KR)

(21) Appl. No.: 18/800,722

(22) Filed: Aug. 12, 2024

(30) Foreign Application Priority Data
Feb. 19, 2024 (KR) 10-2024-0023183

(51) Int. Cl. H01L 27/146

(52) U.S. Cl. CPC H10F 39/8063; H10F 39/8053; H10F 39/8067

(57) ABSTRACT

An image sensor based on an embodiment of the disclosed technology includes a photodiode formed in a pixel area of a substrate, a lens disposed in the pixel area of the substrate, a first reflector disposed in a separation area of the substrate that is arranged between adjacent pixel areas, and a light collection pattern disposed over the substrate.

### CROSS REFERENCE TO RELATED APPLICATION

The present application claims priority to Korean Patent Application No. 10-2024-0023183, filed February 19, the entire contents of which is incorporated herein for all purposes by this reference.

### TECHNICAL FIELD

The present specification relates to an image sensor.

### BACKGROUND

With the development of the information and communication industry and the digitization of electronic devices, image sensors with improved performance are being used in various fields, such as digital cameras, camcorders, mobile phones, personal communication systems (PCS), gaming devices, security cameras, and medical micro cameras.

### SUMMARY

The disclosed technology can be implemented in some embodiments to provide an image sensor capable of efficiently receiving light in an infrared wavelength range.

In addition, the disclosed technology can be implemented in some embodiments to provide an image sensor that can reflect light in a visible wavelength range, preventing the image sensor from receiving light in the visible wavelength range.

An image sensor based on an embodiment of the disclosed technology includes a photodiode formed in a pixel area of a substrate, a lens part disposed in the pixel of the substrate (e.g., by being inserted into the pixel area of the substrate), a first reflection part disposed in a separation area of the substrate, and a light collection pattern disposed on the substrate. In some implementations, the separation area of the substrate is arranged between adjacent pixel areas. In some implementations, the term “lens part” can be used to indicate a suitable type of a lens. In some implementations, the term “reflection part” can be used to indicate a reflector (e.g., first reflector) that includes a material for reflecting light in a certain direction.

The lens part may be disposed by inserting the lens part from an upper surface of the substrate.

The lens part may include a meta lens. The lens part may include a plurality of nano-patterns.

The first reflection part may be disposed by inserting the first reflection part from an upper surface of the substrate.

The image sensor may further include an insulating layer between the substrate and the light collection pattern.

The image sensor may further include a second reflection part disposed in the separation area between the substrate and the light collection pattern.

A refractive index of the lens part may be smaller than a refractive index of the light collection pattern and a refractive index of the substrate.

The refractive index of the lens part may be at least 1 smaller than the refractive index of the substrate.

The refractive index of the lens part may be in the range of 1.4 to 1.6.

A refractive index of the first reflective part may be smaller than a refractive index of the light collection pattern and a refractive index of the substrate.

The refractive index of the first reflection part may be in the range of 1.2 to 1.6.

The thickness of the first reflection part may be at least 1.5 times greater than the thickness of a nano-pattern of the lens part.

The thickness of the nano-pattern of the lens part may be 0.5 to 8 times the width of the pixel.

A length from a lower surface of the substrate to a lower end portion of the nano-pattern of the lens part may be 1 to 8 times the width of the pixel.

An image sensor based on another embodiment of the disclosed technology includes a photodiode formed in a pixel area of a substrate, a lens part (or lens) disposed in the pixel area of the substrate, a first reflection part (or first reflector) disposed in a separation area of the substrate, a light collection pattern disposed over the substrate, and a color filter layer disposed above the substrate and below the light collection pattern, wherein the color filter layer transmits light in an infrared wavelength range. In some implementations, the separation area of the substrate is arranged between adjacent pixel areas.

The color filter layer may not transmit light in a visible light wavelength range.

The lens part may be disposed by being inserted therein from an upper surface of the substrate.

The lens part may include a meta lens, and the lens part may include a plurality of nano-patterns.

The meta lens may scatter the infrared wavelength range, and the first reflection part may reflect the light in the infrared wavelength range incident on the substrate.

The meta lens may not transmit the light in the visible ray wavelength range.

In some embodiments, by inserting the meta lens into the light receiving part, a path of infrared light in the light receiving part of the unit pixel is increased, thereby improving the light receiving efficiency of the infrared light for each unit pixel.

In addition, through the metal lens, it is possible to reduce the reception rate of the light in other wavelength ranges except for the infrared light in the unit pixel, thereby improving the light reception efficiency of the image sensor for infrared light.

### BRIEF DESCRIPTION OF THE DRAWINGS

FIG. 1 is a block diagram schematically showing an image sensor based on an embodiment of the disclosed technology.

FIG. 2 is a cross-sectional view showing the image sensor based on an embodiment of the disclosed technology.

FIG. 3 is a schematic view showing a path of first light beams of the image sensor based on an embodiment of the disclosed technology.

FIG. 4 is a schematic view showing a path of second light beams of the image sensor based on an embodiment of the disclosed technology.

FIG. 5 is a plan view showing an example of the arrangement of a lens part of the image sensor based on an embodiment of the disclosed technology.

FIG. 6 is a plan view showing an example of the arrangement of a lens part of an image sensor based on another embodiment of the disclosed technology.

FIG. 7 is a plan view showing an example of the arrangement of a lens part of an image sensor based on another embodiment of the disclosed technology.

FIG. 8 is a cross-sectional view of an example of the image sensor based on another embodiment of the disclosed technology.

FIG. 9 is a cross-sectional view of the image sensor based on another embodiment of the disclosed technology.

FIG. 10 is a diagram schematically showing an electronic device with the image sensor based on an embodiment of the disclosed technology.

### DETAILED DESCRIPTION

Terms used in some embodiments are not intended to limit the disclosed technology. In some embodiments, the singular form also includes the plural form unless specifically stated in the phrase. The terms “comprises” and/or “comprising” used herein means that the stated component, step, operation, and/or element do not preclude the presence of addition of one or more other components, steps, operations, and/or elements.

In some embodiments, when a first element is “connected to” or “coupled to” a second element, the first element is directly connected or coupled to the second element. In some embodiments, when a first element is “connected to” or “coupled to” a second element, other elements can be interposed between the first element and the second element. In some embodiments, when the first component is “directly connected to” or “directly coupled to” the second component, other components are not interposed between the first element and the second element. In some embodiments, the term “and/or” includes each and every combination of one or more of the items stated.

The spatially relative terms “below,” “beneath,” “lower,” “above,” “upper,” and the like can be used to describe the positions of elements or components relative to other elements or components as shown in the drawings. In some embodiments, the spatially relative terms can be used to include different directions of elements in addition to the directions shown in the drawings. For example, in case of viewing the drawing upside down, an element described as being disposed “below” or “beneath” another element may be disposed “above” another element.

In addition, some embodiments are described with reference to cross-sectional and/or plan views. In addition, in the drawings, thicknesses of films and areas are exaggerated for effective description of technical contents. In some embodiments, an area shown at a right angle may be rounded or have a shape with a predetermined curvature. Therefore, the disclosed technology is not limited to the shapes of the areas shown in the drawings.

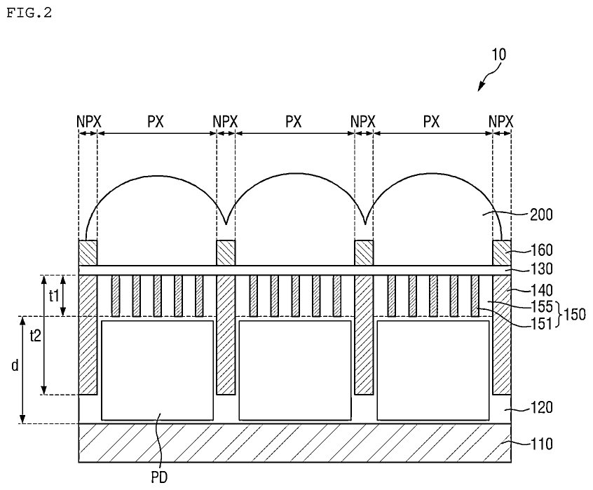

In some implementations, an image sensor may include a photodiode (e.g., PD in FIGS. 2-4 and 8-9) disposed in a pixel area, and a peripheral circuit area. In one example, a unit pixel includes a photodiode and a transfer transistor. The transfer transistor may be disposed between the photodiode and a floating diffusion area to transmit, to the floating diffusion area, charges generated by the photodiode in response to incident light.

In some implementations, the image sensor may include an infrared image sensor for receiving infrared (IR) light rays. An infrared image sensor can only receive light in an infrared wavelength range without receiving light in a visible ray wavelength range.

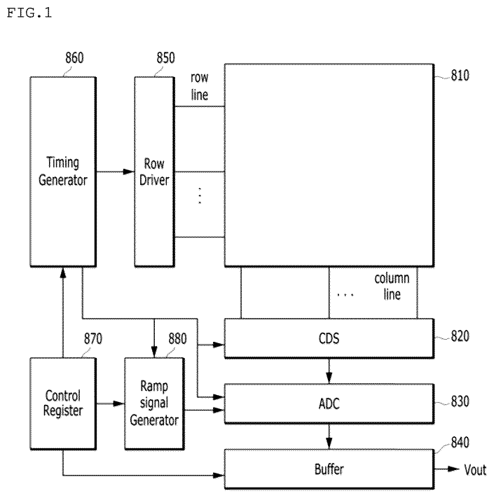

FIG. 1 is a block diagram schematically showing an image sensor 800 based on an embodiment of the disclosed technology. Referring to FIG. 1, the image sensor based on an embodiment of the disclosed technology may include a pixel array 810 in which a plurality of pixels are arranged in a matrix structure, a correlated double sampler (CDS) 820, an analog-digital converter (ADC) 830, a buffer 840, a row driver 850, a timing generator 860, a control register 870, and a ramp signal generator 880.

The pixel array 810 may include a plurality of pixels arranged in a matrix structure. The plurality of pixels may each convert optical image information into electrical image signals and transmit the electric image signals to the CDS 820 through column lines. The plurality of pixels may each be connected to one of the row lines and one of the column lines.

The CDS 820 may hold and sample the electrical image signals received from the pixels of the pixel array 810. For example, the CDS 820 may sample a reference voltage level and a voltage level of the received electrical image signal according to a clock signal provided from the timing generator 860 and transmit an analog signal corresponding to a difference therebetween into the ADC 830.

The ADC 830 may convert the received analog signal into a digital signal and transmit the digital signal to the buffer 840.

The buffer 840 may “latch” or store the received digital signal and sequentially output the latched digital signal to an image signal processor (not shown). The buffer 840 may include a memory to “latch” or store the digital signal and a sense amplifier for amplifying the digital signal.

The row driver 850 may drive or activate the plurality of pixels of the pixel array 810 according to a signal from the timing generator 860. For example, the row driver 850 may generate selection signals for selecting one row line among a plurality of row lines and/or driving signals for driving the one row line.

The timing generator 860 may generate timing signals for controlling the CDS 820, the ADC 830, the row driver 850, and the ramp signal generator 880.

The control register 870 may generate control signal(s) for controlling the buffer 840, the timing generator 860, and the ramp signal generator 880.

The ramp signal generator 880 may generate a ramp signal for controlling the image signal output from the ADC 830 to the buffer 840 according to the control of the timing generator 860.

FIG. 2 is a cross-sectional view showing the image sensor based on an embodiment of the disclosed technology.

Referring to FIGS. 1 and 2, the image sensor 10 may include pixels PX and separation areas NPX between the pixels PX. The image sensor 10 may include a substrate 120, a circuit part 110 that includes circuitry and is disposed under the substrate 120, a reflector (e.g., first reflector) 140 and a lens part 150 disposed in the substrate 120, an insulating layer 130 disposed on the substrate 120, a second reflector 160 on the insulating layer 130, and a light collection pattern 200 on the second reflector 160 and the insulating layer 130.

The circuit part 110 may be disposed on a lower surface of the substrate 120 and may include transistors, an interconnect layer, and an interlayer insulating layer.

The transistors may include an overflow transistor, a transfer transistor, a reset transistor, a driving transistor, and a selection transistor that are formed on the lower surface of the substrate 120.

The interconnect layer may transmit electrical signals generated from photodiodes (e.g., PD in FIGS. 2-4 and 8-9) to an image processing circuit, a display circuit, or others. The interconnect layer may include a conductor such as metal, and include various patterns in the form of lines and vias.

The interlayer insulating layer may cover the lower surface of the substrate 120, the transistors, and the interconnect layer and include an insulating material such as silicon oxide.

The substrate 120 may include a single crystal silicon wafer or an epitaxially grown single crystal silicon layer. The substrate 120 may have a high refractive index. For example, the refractive index of the substrate 120 may be about 2.5 or higher, but is not limited thereto.

In some implementations, each pixel PX supported by the substrate 120 includes a photodetector (e.g., PD in FIGS. 2-4 and 8-9) for detecting incident light received by that pixel PX to generate an electrical signal representing the amount of detected incident light by that pixel PX. Such a photodetector in each pixel PX may be implemented in various configurations, including, for example, a photodiode, a phototransistor, or a photogate. The photodetector such as a photodiode disposed in the pixel PX may be formed by implanting P-type and N-type ions into the substrate 120. P-type ions may include boron (B) ions, and N-type ions may include phosphorous (P) and/or arsenic (As) ions. Such a photodiode serves to receive light incident on the substrate 120 and convert optical signals into electrical signals.

The separation area NPX may be used to separate or distinguish the pixels PX from adjacent pixels PX. In some implementations, the separation area NPX may define one pixel PX.

The separation area NPX may optically and electrically separate and define each pixel PX. The first reflection part 140 and the second reflection part 160 may be disposed in the separation area NPX. The first reflection part 140 of the isolation area NPX may be formed by: forming deep trenches in the substrate 120; and filling the deep trenches with an insulating material. For example, when the first reflection part 140 is formed, it may include performing a deep trench isolation (DTI) process, but is not limited thereto. The first reflection part 140 may serve to totally reflect light incident from the upper surface of the substrate 120.

In the pixel PX, a lens unit 150 may be disposed in the substrate 120. In some embodiments, the lens part 150 may be disposed in the substrate 120 by inserting it from an upper surface of the substrate 120 in a thickness direction.

In some embodiments, the lens part 150 may include a meta lens. In some embodiments, the meta-lens includes nano-patterns that are arranged in a predetermined shape or regularity to focus light and, in some implementations, the dimensions of such nano-patterns may be at or less than the optical wavelength of the light. For example, the lens part 150 may include nano-patterns 151 and insulating pattern 155 disposed between adjacent nano-patterns 151 so that the nano-patterns 151 and insulating pattern 155 are spatially interleaved to form a nano pattern that operates to produce a lensing effect on the light received from the light collection pattern 200. The nano-patterns 151 may include, for example, Si, TiO₂, SiO₂, HfO, AIO, or others, but is not limited thereto. The insulating pattern 155 may include the same material as the substrate 120, but is not limited thereto. When the insulating pattern 155 includes the same material as the substrate 120, the insulating pattern 155 and the substrate 120 may be formed integrally. The lens part 150 may be disposed for each pixel PX. The lens part 150 may have a first thickness t1. The lower surface of the substrate 120 below the lens part 150 may have a first length d. The first thickness t1 and the first length d may be set in connection with the width of the pixel PX, as will be discussed below. A refractive index of the lens part 150 may be smaller than a refractive index of the light collection pattern 200 and a refractive index of the substrate 120. For example, the refractive index of the lens part 150 may be about 1 or more smaller than the refractive index of the substrate 120. As will be described below, the lens part 150 may serve to change a path of first light beams incident from the upper surface of the substrate 120. For example, the lens part 150 may serve to scatter the first light beams. The scattering of light may be more likely to occur at an interface at which there is a large difference in refractive index. In other words, since the lens part 150 based on an embodiment of the disclosed technology may have a refractive index smaller than that of the substrate 120 by about 1 or more, the first light beams incident from the upper surface of the substrate 120 may scatter at an interface between the substrate 120 and the lens part 150. For example, the refractive index of the lens part 150 may be in the range of about 1.4 to about 1.6, but is not limited thereto.

The lens part 150 may have a circular pillar shape, quadrangular pillar shape, or other polygonal pillar shape, but is not limited thereto.

The first reflection part 140 and the second reflection part 160 may be disposed in the separation area NPX. In some implementations, a lens part 150 may be disposed between adjacent first reflection parts 140. The first reflection part 140 may have a second thickness t2. The second thickness t2 may be greater than the first thickness t1. The first reflection part 140 may serve to reflect the first light beams incident from the upper surface of the substrate 120 and reflect the first light beams toward the pixel PX of the substrate 120. To this end, in some embodiments, the refractive index of the first reflection part 140 is smaller than the refractive index of the light collection pattern 200 and the refractive index of the substrate 120. For example, the refractive index of the first reflection part 140 may be in the range of about 1.2 to about 1.6, but is not limited thereto. The second reflection part 160 may perform the same or similar functions as the first reflection part 140 as described above. The second reflection part 160 may serve to reflect the first light beams incident from the light collection pattern 120 and reflect the first light beams toward the pixel PX of the substrate 120. Therefore, in some embodiments, the refractive index of the second reflection part 160 is smaller than the refractive index of the light collection pattern 120. For example, the refractive index of the second reflection part 160 may be in the range of about 1.2 to about 1.6, but is not limited thereto.

The insulating layer 130 may be formed on the substrate 120. The lower surface of the insulating layer 130 may be in direct contact with the first reflection part 140 and the lens part 150. The insulating layer 130 may be configured to support the light collection pattern 200 disposed on the insulating layer 130. The insulating layer 130 may include a low refractive index material, such as silicon oxide. The insulating layer 130 may serve as an anti-reflection layer for preventing the light incident from the light collection pattern 200 from being totally reflected from the lens part 150.

For optical separation between the light collection pattern 200 and the substrate 120, for example, the second reflection part 160 may be disposed in the separation area NPX on the insulating layer 130.

In some implementations, the structural and/or functional features of the second reflection part 160 may be the same or similar as what is discussed above with respect to the second reflection part 160.

The light collection pattern 200 may be disposed between the second reflection parts 160. The light collection pattern 200 may serve to receive the first light beams incident from the outside into the pixel PX. To this end, the light collection pattern 200 may have the shape of a convex lens that is convex upward and may be made of a material with a refractive index significantly different from the refractive index of air. For example, the refractive index of the light collection pattern 200 may be in the range of about 1.5 to about 1.7, but is not limited thereto. As shown in FIG. 1, the light collection pattern 200 may be consecutively disposed in the pixel PX and the separation area NPX and may be formed so that a convex lens-shaped end portion thereof is positioned at a central portion of the pixel PX. For example, the light collection pattern 200 may be disconnected from the separation area NPX, and in this case, a plurality of light collection patterns 200 may be positioned in each pixel PX.

Hereinafter, the functions of the lens part 150 and the first reflection part 140 of the image sensor 10 described above in FIG. 2 will be described in detail.

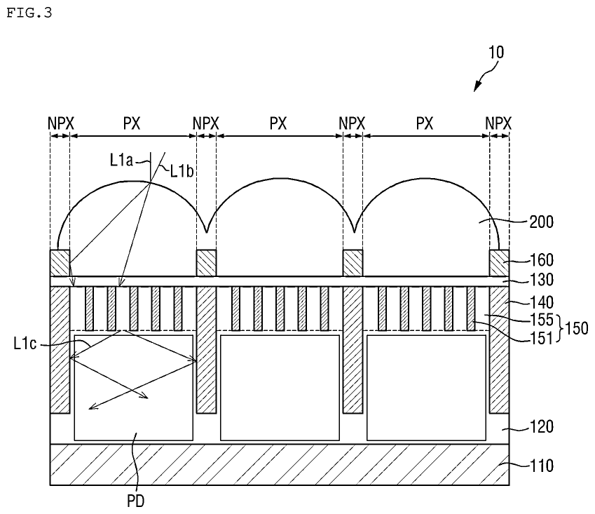

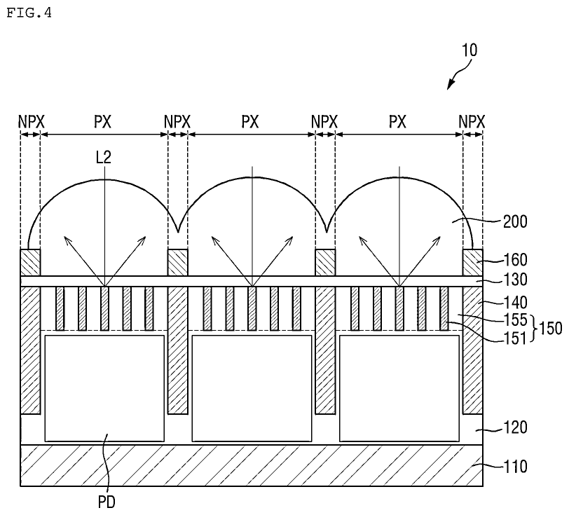

FIG. 3 is a schematic view showing a path of first light beams of the image sensor based on an embodiment of the disclosed technology. FIG. 4 is a schematic view showing a path of second light beams of the image sensor based on an embodiment of the disclosed technology. FIG. 3 shows 1-1 light beam La and 1-2 light beam L1b. The first light beams described above in FIG. 2 may include the 1-1 light beam L1a and the 1-2 light beam L1b. The first light beams L1a and L1b may be in the infrared wavelength band. For example, a wavelength range of the first light beams L1a and L1b may be in the range of about 750 nm to 10000 nm.

As shown in FIG. 3, the 1-1 light beam L1a and the 1-2 light beam L1b may each be refracted from the light collection pattern 200. As described above, since the refractive index of the light collection pattern 200 may be greater than that of air, the first light beams L1a and L1b may be incident on the light collection pattern 200 with refraction angles as shown in FIG. 3. The 1-1 light beam L1a may be totally reflected from the second reflection part 160 and incident on the pixel PX of the substrate 120. As described above in FIG. 2, each of the reflection parts 140 and 160 may serve to reflect the incident 1-1 light beam L1a and reflect the 1-1 light beam L1a toward the pixel PX of the substrate 120. To this end, in some embodiments, the refractive indices of the first reflection parts 140 and 160 are smaller than the refractive index of the light collection pattern 200 and the refractive index of the substrate 120. For example, the refractive indices of the reflection parts 140 and 160 may be in the range of about 1.2 to about 1.6, but is not limited thereto. Since the reflection parts 140 and 160 serve to totally reflect the 1-1 light beam L1a incident on the separation area NPX into the pixel PX of the substrate 120, the amount of received light of the 1-1 light beam L1a in the pixel PX can be increased. To make the 1-1 light beam La incident on the photodiode of the pixel PX by the first reflection part 140, the second thickness t2 of the first reflection part 140 is preferably about 1.5 times or more than the first thickness t1. In addition, as described above, since the first reflection part 140 is formed by forming the deep trenches in the substrate 120 and filling the deep trenches with the insulating material, it is possible to shorten a process time when the first reflection part 140 has a thickness of about 8 times or less the first thickness t1.

Furthermore, the 1-2 light beam L1b incident on the light collection pattern 200 may pass through the insulating layer 130 and then may be directed toward the substrate 120 and the lens part 150 disposed in the substrate 120. An optical path of the 1-2 light beam L1b incident on the upper surface of the substrate 120 may be changed by the lens part 150. For example, the 1-2 light beam L1b may pass through the lens part 150 and then may be scattered at a specific angle (see L1c in FIG. 3). As described above in FIG. 2, the photodiode serves to receive the light incident on the substrate 120 and convert the optical signal into an electrical signal. In some implementations, the amount of light received by the photodiode may vary depending on the wavelength range of the incident light. For example, as the wavelength range of the incident light increases, the amount of light received by the photodiode may decrease. The image sensor 10 based on an embodiment of the disclosed technology may serve to receive the first light beams L1a and L1b in the infrared wavelength range and convert optical signals of the first light beams L1a and L1b into electrical signals. However, since the first lights beams L1a and L1b have a long wavelength in the infrared wavelength range, the amount of light received by the photodiode may be decreased. To address this issue, in the image sensor 10 implemented based on an embodiment of the disclosed technology, the lens part 150 may be disposed in the substrate 120 (e.g., by being inserted from the upper surface of the substrate 120), and the lens part 150 may scatter the light passing through the lens part 150 at a greater angle. Since a length of an optical path of the scattered 1-3 light beams L1c increases compared to other light beams linearly passing through the photodiode, the amount of the 1-3 light beams L1c (or infrared rays) received by the photodiode in the pixel PX may be increased. To effectively increase the length of the optical path of the 1-3 light beams L1c by optically scattering the incident 1-2 light beam L1b by the lens part 150, in some embodiments, the first thickness t1 may be about 0.5 times the width of the pixel PX. Furthermore, since the lens part 150, similar to the first reflection part 140, is formed by forming the deep trenches in the substrate 120 and filling the deep trenches with the material of the lens part, it is possible to shorten the process time when the lens part 150 becomes about 8 times or less the width of the pixel PX. A first length d from the lower surface of the substrate 120 to a lower end portion of the lens part 150 may be 1 to 8 times the width of the pixel PX, but is not limited thereto.

In some embodiments, as described above, since the image sensor 10 based on an embodiment of the disclosed technology serves to receive the first light beams L1a and L1b in the infrared wavelength range and converts the optical signals of the first light beams L1a and L1b into electrical signals, light in a wavelength range other than the infrared wavelength range may be prevented from entering the photodiode.

As shown in FIG. 4, second light beams L2 in the visible ray wavelength range incident on the upper surface of the substrate 120 may not enter the photodiode of the pixel PX by being totally reflected by the lens part 160. As described above, the refractive index of the lens part 150 may be smaller than the refractive index of the light collection pattern 200 and the refractive index of the substrate 120, and for example, the refractive index of the lens part 150 may be about 1 smaller than the refractive index of the substrate 120. Therefore, the second light beams L2 in the visible ray wavelength range incident on the upper surface of the substrate 120 may not enter the photodiode of the pixel PX by being totally reflected by the lens part 150. In other words, the image sensor 10 based on an embodiment of the disclosed technology may increase the received amount of each of the first light beams L1a and L1b in the infrared wavelength range through total reflection and scattering using the reflectors 140 and 160 and the lens part 150, and at the same time, decrease the received amount of second light beams L2 in the visible ray wavelength range by inducing total reflection using the lens part 150. As a result, it is possible to increase the light receiving efficiency of the image sensor 10.

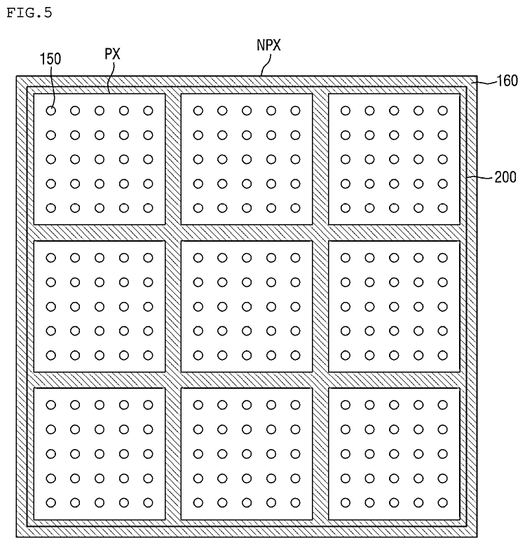

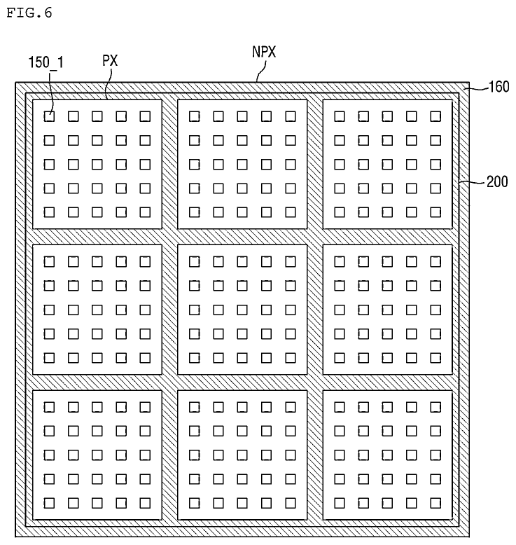

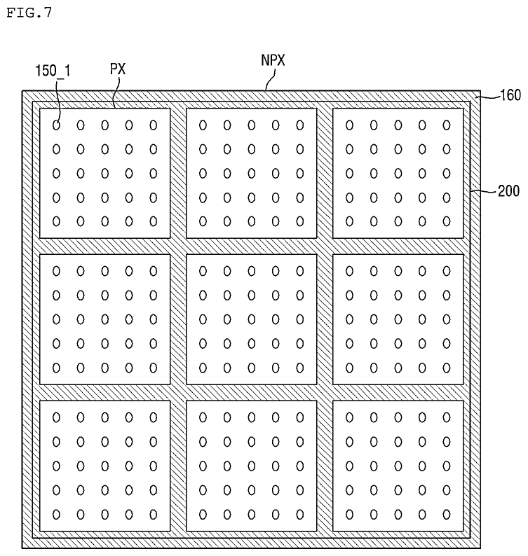

FIG. 5 is a plan view showing an example of the arrangement of a lens part of the image sensor based on an embodiment of the disclosed technology. FIG. 6 is a plan view showing an example of the arrangement of a lens part of an image sensor based on another embodiment of the disclosed technology. FIG. 7 is a plan view showing an example of the arrangement of a lens part of an image sensor based on another embodiment of the disclosed technology.

Referring to FIG. 2 and FIGS. 5 to 7, the arrangement of nano-patterns of the lens part 150 of the image sensor 10 is shown.

As shown in FIG. 5, the nano-patterns of the lens part 150 may be disposed to be spaced apart from each other in row and column directions in the pixel PX. A planar shape of the nano-pattern may be a circular shape.

As shown in FIG. 6, the nano-patterns of the lens part 150 may be disposed to be spaced apart from each other in row and column directions in the pixel PX. The planar shape of the nano-pattern may be a quadrangular shape. However, the planar shape of the nano-pattern is not limited thereto, and may be various polygonal shape, such as a triangle and a pentagon and may also be an irregular shape.

As shown in FIG. 7, the nano-patterns of the lens part 150 may be disposed to be spaced apart from each other in row and column directions in the pixel PX. The planar shape of the nano-pattern may be an oval shape. Although FIG. 7 shows that the nano-pattern has an oval shape extending in the column direction, the present specification is not limited thereto and may also be an oval shape extending in the row direction.

Hereinafter, an image sensor based on another embodiment of the disclosed technology will be described.

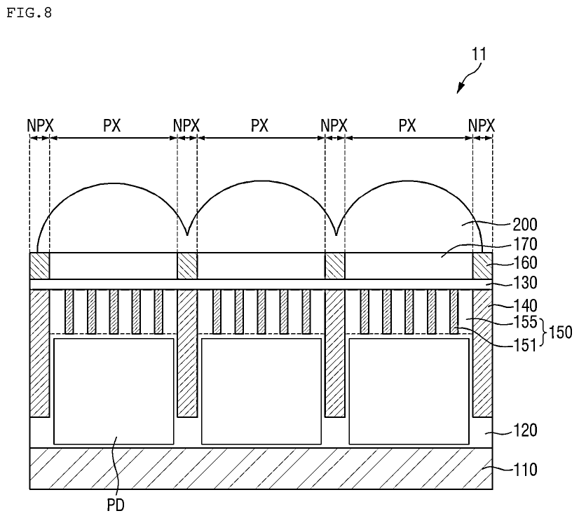

FIG. 8 is a cross-sectional view of the image sensor based on another embodiment of the disclosed technology.

Referring to FIG. 8, the image sensor 11 based on an embodiment differs from the image sensor shown in FIG. 2 in that the color filter layer 170 may be disposed between the light collection pattern 200 and the insulating layer 130.

In some embodiments, a color filter layer 170 may be disposed between the light collection pattern 200 and the insulating layer 130. The color filter layer 170 may be disposed in the pixel PX. In some embodiments, the color filter layer 170 may block wavelengths corresponding to visible light and transmit the remaining wavelengths. In one example, the color filter layer 170 may block wavelengths corresponding to visible light and transmit wavelengths corresponding to the infrared wavelength range. In some embodiments, only infrared light in the infrared wavelength range may be incident on the color filter layer 170. For example, the color filter layer 170 may include a red color filter for transmitting red light and absorbing green and blue light, a green color filter for transmitting green light and absorbing red and blue light, and a blue color filter for transmitting blue light and absorbing red and green light and may have a structure in which the above-described red color filter, green color filter, and blue color filter are stacked. The stacking order of the red color filter, the green color filter, and the blue color filter is not limited.

In an embodiment, the color filter layer 170 for absorbing light in the visible ray wavelength range may be further disposed between the light collection pattern 200 and the insulating layer 130 to increase the received amount of the first light beams L1a and L1b (see FIG. 3) in the infrared wavelength range of the image sensor 10 and increasing light receiving efficiency.

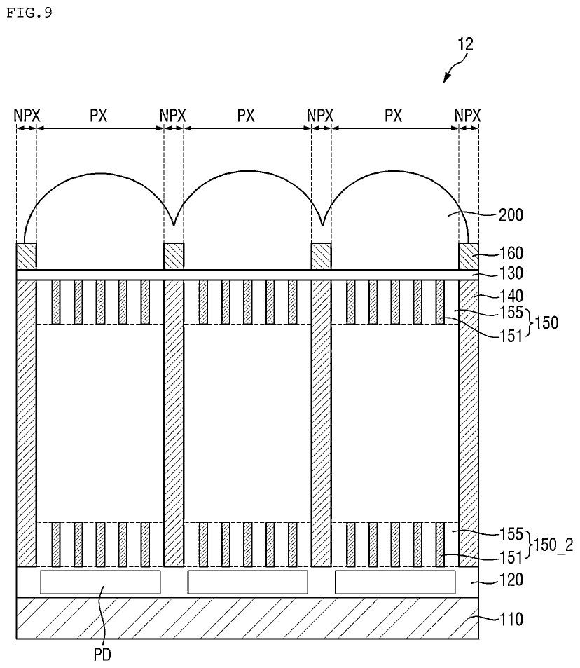

FIG. 9 is a cross-sectional view of the image sensor based on another embodiment of the disclosed technology.

Referring to FIG. 9, the image sensor 12 differs from the image sensor 10 shown in FIG. 3 in that two or more lens parts 150 and 150_2 may be disposed in the pixel area PX. As described above, the image sensor 10 shown in FIG. 2 may increase the received amount of each of the first light beams L1a and L1b in the infrared wavelength range through total reflection by using reflections at the reflectors 140 and 160 and the lens part 150 and scattering of the light at a greater angle after passing through the lens part 150, and at the same time, decrease the received amount of second light beams L2 in the visible ray wavelength range by inducing total reflection using the lens part 150. As a result, it is possible to increase the light receiving efficiency of the image sensor 10. As shown in FIG. 9, in some embodiments, the image sensor 12 may further include the second lens part 150_2 disposed at a lower end portion of the first reflection part 140. Like the lens part 150, the second lens part 150_2 may include a plurality of nano-patterns 151 and an insulating pattern 155 between adjacent nano-patterns 151. As described above in FIG. 2, the refractive index of the lens part 150 may be smaller than the refractive index of the light collection pattern 200 and the refractive index of the substrate 120. For example, the refractive index of the lens part 150 may be about 1 or more smaller than the refractive index of the substrate 120. The refractive index of the second lens part 150_2 may be the same as the refractive index of the lens part 150. The light passing through the lens part 150 may pass through the substrate 120. Some of the light passing through the substrate 120 may be totally reflected at the interface between the substrate 120 and the second lens part 150_2 due to a difference in refractive indices between the substrate 120 and the second lens part 150_2. Since the light totally reflected at the interface between the second lens part 150_2 and the substrate 120 may be scattered at a great angle by the second lens part 150_2 to increase the optical path in the substrate 120, there is an advantage that the amount of light received by the photodiode can be further increased compared to the embodiment of FIG. 3.

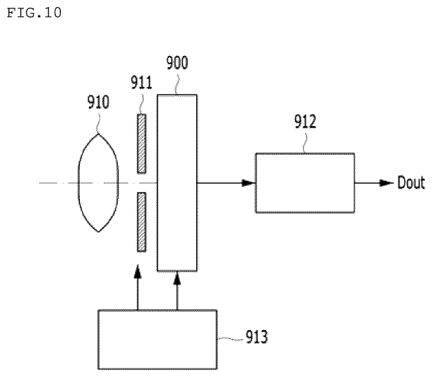

FIG. 10 is a diagram schematically showing an electronic device based on an embodiment of the disclosed technology.

Referring to FIGS. 1 to 10, the electronic device based on an embodiment of the disclosed technology may include a camera capable of capturing still images or moving images. The electronic device may include an optical system 910 (or an optical lens), a shutter unit 911, an image sensor 900, and a driver 913 and signal processor 912 for controlling/driving the shutter unit 911. At least one of the image sensors 900 described above in FIGS. 1 to 9 may be applied to the image sensor 900 shown in FIG. 10.

The optical system 910 may guide image light (incident light) from a subject to the pixel array 810 (see FIG. 1) of the image sensor 900. The optical system 910 may include a plurality of optical lenses. The shutter unit 911 may control a light radiation period and a shielding period for the image sensor 900. The driver 913 may control transmission operations of the image sensors 10, 11, and 12 and a shutter operation of the shutter unit 911. The signal processor 912 performs various types of signal processing on signals output from the image sensor 900. An image signal Dout after signal processing may be stored in a storage medium, such as a memory, or output to a monitor or display or others.

Only a few embodiments and examples are described. Enhancements and variations of the disclosed embodiments and other embodiments can be made based on what is described and illustrated in this patent document.

What is claimed is:

1. An image sensor comprising:
a photodetector in a pixel area of a substrate to detect light;
a lens in the pixel area of the substrate to focus incident light to the photodetector;
a reflector disposed in a separation area of the substrate adjacent to the pixel area; and
a light collection pattern disposed over the substrate to collect incident light and direct collected incident light to the lens.

2. The image sensor of claim 1, wherein the lens is disposed by being inserted therein from an upper surface of the substrate.

3. The image sensor of claim 1, wherein the lens includes a structure of nano-patterns to focus incident light to the photodetector, or includes a meta lens.

4. The image sensor of claim 1, wherein the reflector is disposed between adjacent lenses of adjacent pixel areas on the substrate.

5. The image sensor of claim 1, further comprising an insulating layer disposed over the substrate and below the light collection pattern.

6. The image sensor of claim 1, further comprising a second reflector disposed in an area over the substrate and below the light collection pattern corresponding to the separation area.

7. The image sensor of claim 1, wherein a refractive index of the lens is smaller than a refractive index of the light collection pattern and a refractive index of the substrate.

8. The image sensor of claim 7, wherein the refractive index of the lens is at least 1 smaller than the refractive index of the substrate.

9. The image sensor of claim 8, wherein the refractive index of the lens is in a range of 1.4 to 1.6.

10. The image sensor of claim 1, wherein a refractive index of the reflector is smaller than a refractive index of the light collection pattern and a refractive index of the substrate.

11. The image sensor of claim 10, wherein the refractive index of the reflector is in a range of 1.2 to 1.6.

12. The image sensor of claim 3, wherein a thickness of the reflector is at least 1.5 times greater than a thickness of a nano-pattern of the lens.

13. The image sensor of claim 3, wherein a thickness of the nano-pattern of the lens is 0.5 to 8 times a width of the pixel area.

14. The image sensor of claim 3, wherein a length from a lower surface of the substrate to a lower end portion of the nano-pattern of the lens is 1 to 8 times a width of the pixel.

15. An image sensor comprising:
a photodetector formed in a pixel area of a substrate;
a lens disposed in the pixel area of the substrate;
a first reflector disposed in a separation area of the substrate that is arranged between adjacent pixel areas;
a light collection pattern disposed over the substrate; and
a color filter layer disposed above the substrate and below the light collection pattern,
wherein the color filter layer transmits light in an infrared wavelength range.

16. The image sensor of claim 15, wherein the color filter layer does not transmit light in a visible light wavelength range.

17. The image sensor of claim 15, wherein the lens includes a meta lens.

18. The image sensor of claim 17, wherein the meta lens includes a plurality of nano-patterns.

19. The image sensor of claim 18, wherein the meta lens scatters light in the infrared wavelength range, and
the first reflector reflects the light in the infrared wavelength range incident on the substrate.

20. The image sensor of claim 18, wherein the meta lens does not transmit the light in a visible light wavelength range.
